(19) United States
(12) Patent Application Publication
(10) Pub. No.: US 2012/0091514 A1
(43) Pub. Date: Apr. 19, 2012

(54) Semiconductor Junction Diode Device And Method For Manufacturing The Same

(76) Inventors: Qingqing Liang, Lagrangeville, NY (US); Huicai Zhong, San Jose, CA (US); Huilong Zhu, Poughkeepsie, NY (US)

(21) Appl. No.: 13/377,958

(22) PCT Filed: Feb. 27, 2011
(86) PCT No.: PCT/CN2011/071352

§ 371 Date: Dec. 13, 2011

(30) Foreign Application Priority Data
May 19, 2010 (CN) 201010183446.4

(51) Int. Cl. H01L 29/808; H01L 21/337

(52) U.S. Cl. 257/279; 438/194; 257/256; 257/E21.445; 257/E29.312

(57) ABSTRACT

A semiconductor junction diode device structure and a method for manufacturing the same are provided, where a gate of the diode device structure is directly formed on the substrate, a P-N junction is formed in the semiconductor substrate, a first contact is formed on the gate, and a second contact is formed on the doped region at both sides of the gate, the first contact and the second contact acting as cathode/anode of the diode device, respectively. The diode device of this structure occupies a small area, and its forming process may be integrated in a gate-last integration process of MOSFET devices, which needs no additional mask and costs and has a high integration level.

This application is a National Phase application of PCT Application No. PCT/CN2011/071352, filed on Feb. 27, 2011, entitled “Semiconductor Junction Diode Device And Method For Manufacturing The Same”, which claimed priority to Chinese Application No. 201010183446.4, filed on May 19, 2010. Both the PCT Application and Chinese Application are incorporated herein by reference in their entireties.

### FIELD OF THE INVENTION

The present invention generally relates to a semiconductor device and a method for manufacturing the same, and specifically, to a semiconductor junction-type diode device that may be integrated in a gate replacement process and a method for manufacturing the same.

### BACKGROUND OF THE INVENTION

In designing a VLSI (Very Large Scale Integrated Circuits) and an analog circuit, application of a diode devices, such as ESD (Electro Static Discharge) and Schottkey diode, is essential. Currently, a traditional diode device mainly uses the source/drain (101) of an MOSFET as the cathode/anode of a diode. As illustrated in FIG. 1, because the electric properties of the diode in this structure are constrained by the ion implantation conditions for the MOSFET device, in order to change the electric properties of the diode, an additional mask is required to implement a source/drain implantation condition different from MOSFET, which will cause additional process and cost; further, a large area is also required to implement this structure.

Therefore, it is desirable to provide a diode device structure that is more advantageous for process integration and has a smaller area.

### SUMMARY OF THE INVENTION

The present invention provides a method for manufacturing a semiconductor junction diode device structure, comprising: providing a semiconductor substrate; forming a first doped region having a first type of doping in the semiconductor substrate; forming a gate directly covering a portion of the substrate where the first doped region is disposed and forming a P-N junction within the semiconductor substrate; and forming a first contact on the gate, and forming a second contact on the semiconductor substrate at both sides of the gate, the first contact and the second contact being defined as cathode/anode of the diode device, respectively. The gate is formed by a semiconductor or compound semiconductor material.

The present invention further provides a semiconductor junction diode device structure formed by the above method, the device structure comprising: a semiconductor substrate; a first doped region having a first type of doping and formed in the semiconductor substrate; a gate directly covering a portion of the substrate where the first doped region is disposed, and a P-N junction formed within the semiconductor substrate; and a first contact formed on the gate, and a second contact formed on the semiconductor substrate at both sides of the gate, the first contact and the second contact being defined as cathode/anode of the diode device, respectively. The gate is formed by a semiconductor or compound semiconductor material.

By using the diode device structure according to the present invention, the device area is effectively reduced, with the process margin being increased. Additionally, the method for manufacturing the diode device may be effectively integrated in the gate replacement process, which is more convenient for process integration.

### BRIEF DESCRIPTION OF THE DRAWINGS

FIG. 1 illustrates a top view of an existing diode device structure;

FIG. 2 illustrates a top view of a diode device structure at an initial manufacturing stage according to a first embodiment of the present invention;

FIG. 2A illustrates an AA′-direction view of FIG. 2;

FIG. 2B illustrates a BB′-direction view of FIG. 2;

FIG. 3 illustrates a top view of the diode device structure at a later manufacturing stage according to the first embodiment of the present invention;

FIG. 3A illustrates an AA′-direction view of FIG. 3;

FIG. 3C illustrates a CC′-direction view of FIG. 3;

FIG. 4 illustrates a top view of a diode device at an initial manufacturing stage according to a second embodiment of the present invention;

FIG. 4A illustrates an AA′-direction view of FIG. 4;

FIG. 4B illustrates an BB′-direction view of FIG. 4;

FIG. 5 illustrates a top view of the diode device structure at a later manufacturing stage according to the second embodiment of the present invention;

FIG. 5A illustrates an AA′-direction view of FIG. 5; and

FIG. 5C illustrates a CC′-direction view of FIG. 5;

### DETAILED DESCRIPTION OF THE INVENTION

The present invention generally relates to a semiconductor device and a method for manufacturing the same, and specifically, to a semiconductor junction-type diode device structure that may be integrated in a gate-last process and a method for manufacturing the same. The disclosure below provides many different embodiments or examples to implement different structures of the present invention. In order to simplify the disclosure of the present invention, components and arrangements of particular examples will be described below. Of course, they are only exemplary and not intended to limit the present invention. Besides, the present invention may repeat reference numbers and/or letters in different examples. Such repetition is for the purpose of simplification and clarity, without indicating the relationships between various embodiments and/or arrangements in discuss. Besides, the present invention provides examples of various particular processes and materials, but those skilled in the art would be aware of the applicability of other processes and/or use of other materials. Additionally, the structure of a first feature being “on” a second feature as described below may comprise an embodiment that the first and second features form a direct contact or an embodiment that another feature is formed between the first and second features such that the first and second features may not directly contact.

Hereinafter, detailed description will be made according to various steps of the embodiments of the present invention and a semiconductor device obtained therefrom.

### First Embodiment

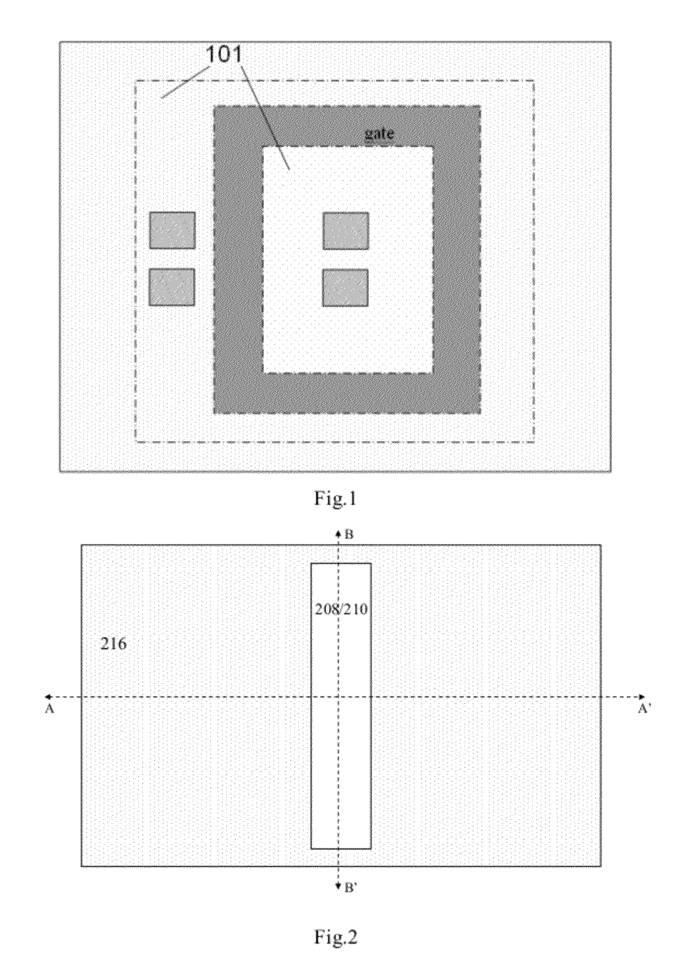

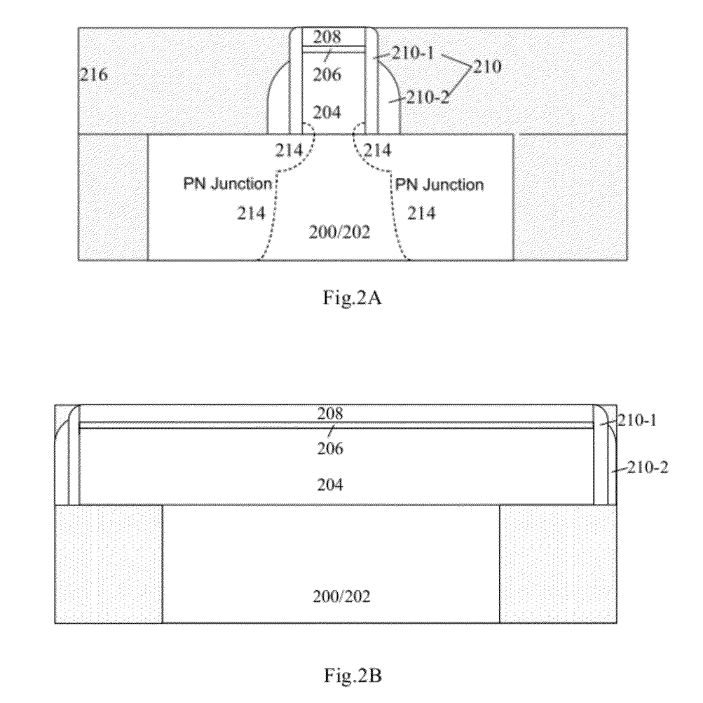

At step S01, a semiconductor substrate 200 is provided, as illustrated in FIG. 2A. In this embodiment, the substrate 200 comprises a silicon substrate (for example, a wafer) of a crystal structure, but may also comprise other basic semiconductor or compound semiconductor, for example, Ge, SiGe, GaAs, InP, SiC or diamond, etc. Based on the known design requirements in the prior art (for example, a P-type substrate or an n-type substrate), the substrate 200 may comprise various kinds of doping configurations. Besides, the substrate 200 may alternatively comprise an epitaxial layer, may be manipulated by stress to enhance the performance, and may comprise a silicon on insulator (SOI) structure.

At step S02, a first doped region 202 having a first type of doping is formed within the semiconductor substrate 200. The first doped region 202 may be implemented by well doping in the conventional process, such that the first doped region 202 has a n-type or p-type doping, and the doping type of the first doped region 202 is defined as the first type of doping, as shown in FIG. 2A.

At step S03, a gate 204 is formed to cover a portion of the semiconductor substrate 200 where the first doped region is disposed, and a P-N junction is formed within the semiconductor substrate, as illustrated in FIG. 2 (top view), FIG. 2A (AA′-direction view), and FIG. 2B (BB′-direction view).

First, on a portion of the semiconductor substrate 200 where the first doped region 202 is disposed, a gate 204 having a first type of doping is formed, as illustrated in FIG. 2 (top view) and FIG. 2B (BB′ direction view). It may be formed by depositing the gate 204 on the semiconductor substrate 200 and performing ion implantation with a dopant(s) of the same doping type as the first doped region into the gate 204, or may be formed by performing in-situ doped epitaxy of a gate material with a dopant(s) of the same doping type as the first doped region 202. The gate 204 may be formed by a semiconductor or compound semiconductor material, for example, one of Si, Ge, SiGe, GaAs, InP, SiC and diamond, etc. Preferably, a cap layer may be further formed on the gate 204, and afterwards the gate 204 and the cap layer may be patterned together. The cap layer may protect the gate 204 and act as an etching stop layer. In the embodiments of the present invention, the cap layer comprises a first oxide cap layer 206 that may be an oxide material such as SiO₂, etc., and a second nitride cap layer 208 that may be a nitride material, such as SiN, etc.

Afterwards, a P-N junction is formed. The P-N junction may be formed by a traditional process, such as implantation, for forming a semiconductor device by the gate-last process. The first sidewall spacers 210-1 are firstly formed on sidewalls of the gate 204, and doping ions implantation for the shallow junction is then performed. Implantation for the shallow junction region generally comprises ion implantation for source/drain extension regions and/or halo regions. Then the second sidewall spacers 210-2 are formed, and doping ions implantation for source/drain regions is performed. The ion implantation for the shallow junction and source/drain are the second type of doping, thereby forming a second doped region 214 that has a second type of doping. In another embodiment, the second doped region 214 may be formed by only one of the shallow-junction doping ions implantation and the source/drain doping ions implantation. The doping type is the second type of doping. After diffusion, a P-N junction as illustrated in FIG. 2A is formed at the interface between the first doped region 202 and a second doped region 214 which has a second type of doping. The second type of doping is opposite to the first type of doping.

Next, an insulating dielectric layer 216 is formed to cover the device. The insulating dielectric layer 216 may be formed by depositing (such as by PECVD) insulating dielectric layer 216 on the device, and then performing planarizing process to the insulating dielectric layer 216. The insulating dielectric layer 216 may be, but not limited to, for example, undoped SiO₂, doped SiO₂ (for example, Borosilicate glass, boron phosphorous silicate glass (BPSG)), etc.

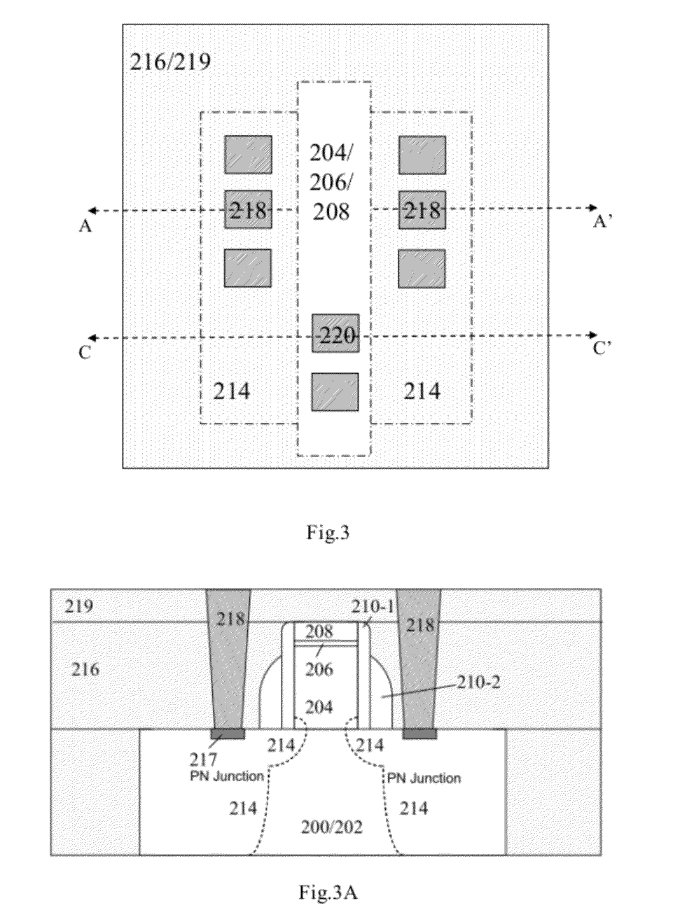

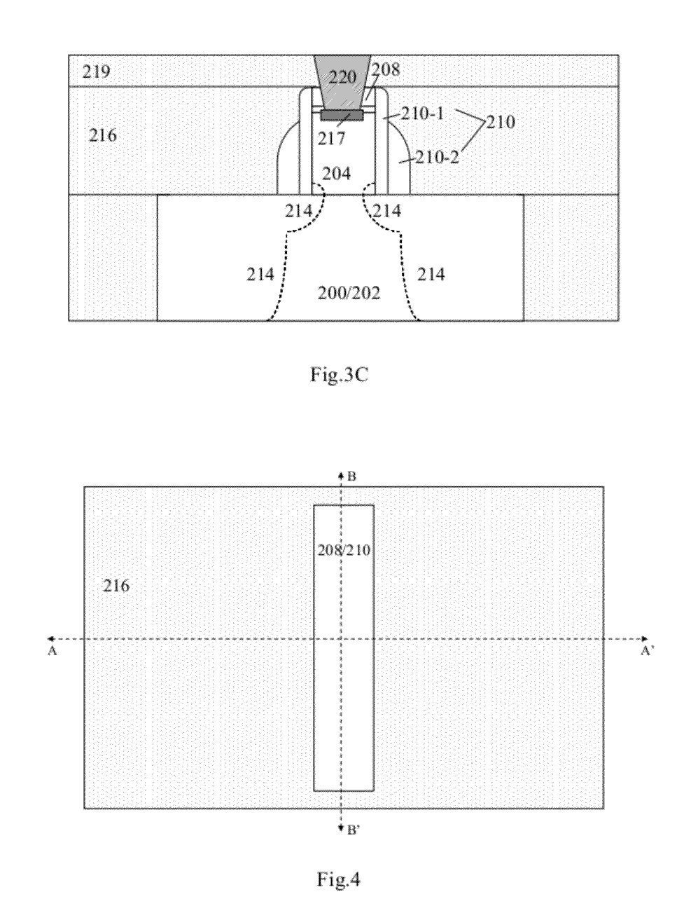

At step S04, a first contact(s) 220 is formed on the gate 204, and second contacts 218 are formed on the semiconductor substrate 200 at both sides of the gate 204. The first 220 and the second contacts 218 are defined as the cathode/anode of the diode device, respectively, as illustrated in FIG. 3 (top view), FIG. 3A (AA′ direction view) and FIG. 3C (CC′ view). The process is compatible with the dummy-gate removal of the CMOS gate-last process, where the gate 204 as a dummy-gate in the CMOS device is removed.

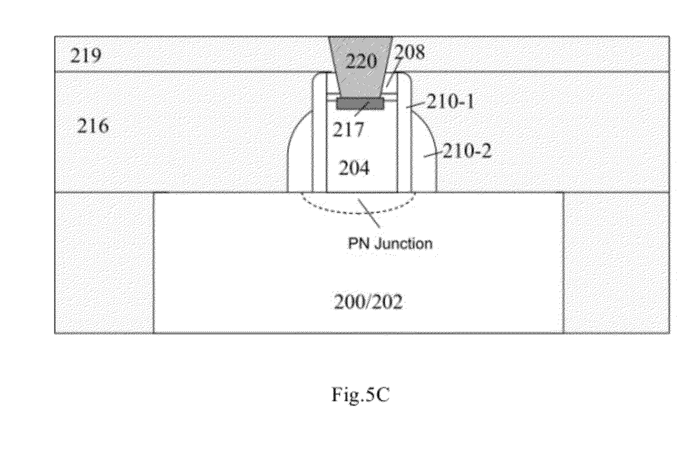

Preferably, before forming the source/drain contacts 218 and the body contact 220, a metal silicide layer 217 may be formed between the source/drain contacts 218 and a portion of the substrate 200 underneath the source/drain contacts 218, and also between the body contact 220 and the gate 204, as illustrated in FIG. 5A (AA′ direction view) and FIG. 5C (CC′ direction view). Firstly, a second insulation dielectric layer 219 is formed on the insulation dielectric layer 216. The second insulation dielectric layer 219 may be, but not limited to, for example, undoped SiO₂, doped SiO₂ (for example, Borosilicate glass, boron phosphorus silicate glass (BPSG)), etc. Next, selective etching is performed to form contact holes on the source region and drain region 214, i.e., portions of the semiconductor substrate in the second doped region at both sides of the gate 204 and on the gate 204, respectively. Preferably, metal silicidation may be performed, and then the metal that has not reacted is removed, thereby forming a metal silicide layer 217 to reduce the contact resistance and improve the conductivity. The material of the metal silicidation may be, for example, any one or combinations of Co, Ni, Mo, Pt, and W, etc. Thereafter, the contact holes are filled with a metal material, for example, W, to form the second contacts 218 in source/drain regions and the first contact 220, as illustrated in FIG. 3 (bottom view), FIG. 3A (AA′ direction view), and FIG. 3C (CC′ direction view). The first contact 220 acts as an anode or cathode of the diode device, and the source/drain second contacts 218 acts as cathodes or anodes of the diode device.

### Second Embodiment

In the second embodiment, the P-N junction of the diode device structure is formed in a different manner from the first embodiment. Hereinafter, the aspects of the second embodiment that are different from the first embodiment will be explained. Those parts which have not been described should be interpreted as having the same steps, methods or processes as the first embodiment, and therefore detailed description thereof is omitted.

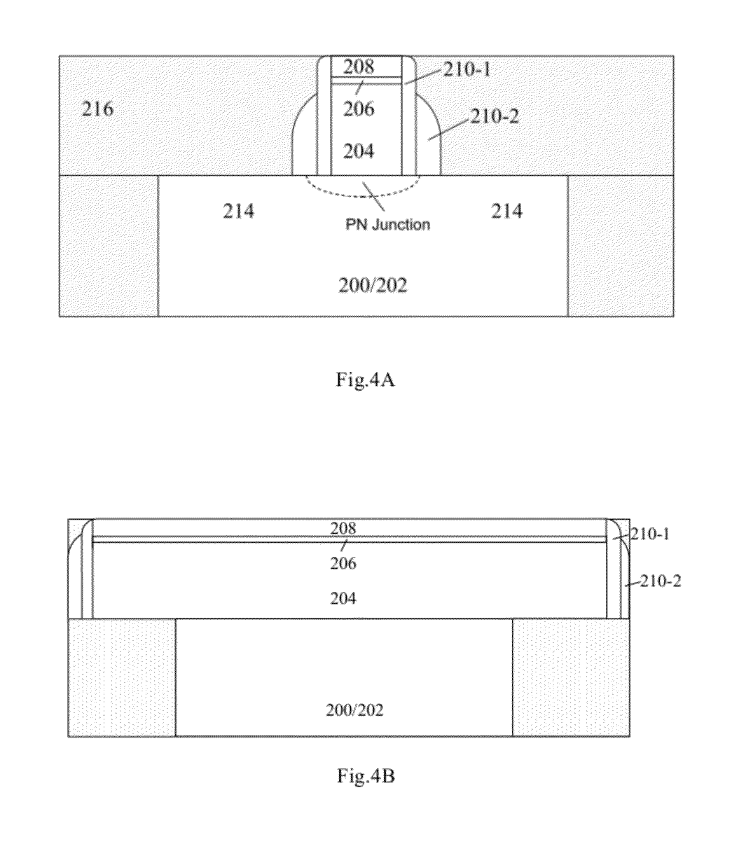

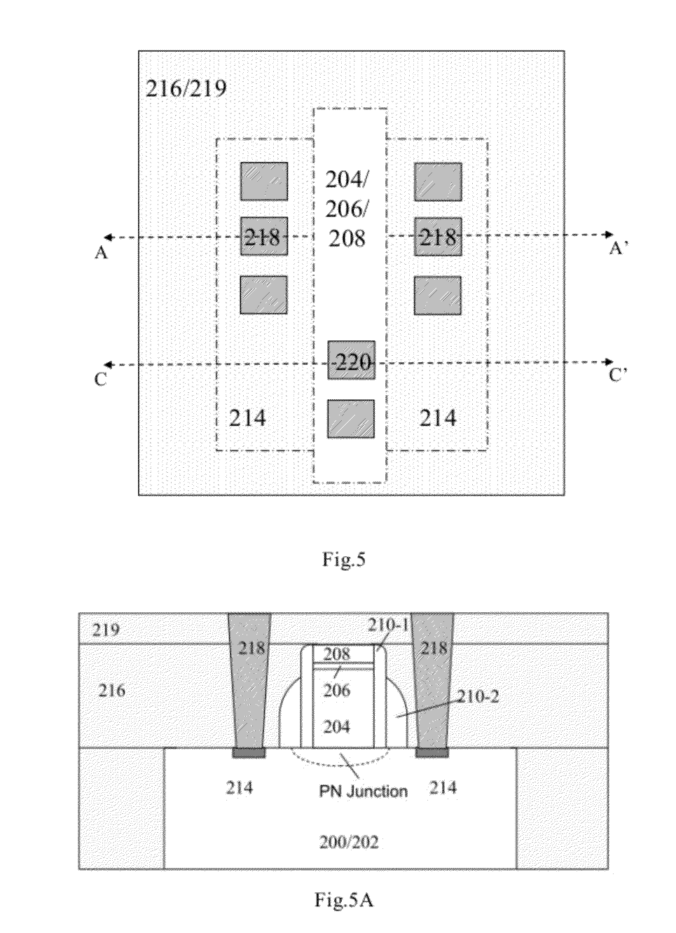

At step S03, a gate 204 is formed to cover a portion of the semiconductor substrate 200 where the first doped region is disposed, and a P-N junction is formed within the semiconductor substrate 200, as illustrated in FIG. 4 (top view), FIG. 4A (AA′ direction view), and FIG. 4B (BB′ direction view).

Firstly, a gate having a second type of doping is formed on the portion of the semiconductor substrate where the first doped region is disposed. As illustrated in FIG. 4A (AA′ direction view), it may be formed by depositing the gate 204 on the semiconductor substrate 200, and implanting dopants with an opposite doping type to that of the first doped region into the gate 204. It may also be formed by selecting a dopant with an opposite doping type to that of the first doped region to perform in-situ doped epitaxy of a gate material. The dopants are then diffused to form the P-N junction of FIG. 4A between the gate having a second type of doping and the first doped region having a first type of doping underneath the gate. The gate 204 may be formed with a semiconductor or compound semiconductor material, for example, Si, Ge, SiGe, GaAs, InP, SiC, or diamond, etc.

Preferably, a cap layer may be further formed on the gate 204, and then the gate 204 and the cap layer may be patterned. The cap layer may protect the gate 204 and act as an etching stop layer. In the embodiments of the present invention, the cap layer comprises a first oxide cap layer 206 that may be an oxide material, such as SiO₂, and a second nitride cap layer 208 that may be a nitride material, such as SiN, etc.

Then, sidewall spacers may be further formed as required. Next, preferably, when performing source/drain ion implantation of the first type of doping, the device is subjected to implantation, thereby forming a second doped region 214 within the semiconductor at both sides of the gate 204, the second doped region 214 having a different concentration from the first doped region 202. Because the type of doping is the same as that of the first doped region, the second doped region 214 is not illustrated in the figure. Thus, when forming contacts on the second doped region in subsequent steps, the contact resistance may be reduced, with the electrically conductive performance being enhanced. Then, an insulation dielectric layer 216 is formed to cover the device.

At step S04, a first contact 220 is formed on the gate 204, and second contacts 218 are formed on the semiconductor substrate 200 at both sides of the gate 204. The first 220 and the second contacts 218 are defined as cathode/anode of the diode device, respectively, as illustrated in FIG. 5 (top view), FIG. 5A (AA′ direction view), and FIG. 5C (CC′ direction view). Because its implementation steps are the same as those of the first embodiment, the repetitious details are not given here.

The present invention further provides a diode device structure that is formed according to the above manufacturing method. With reference to FIG. 3 (top view), FIG. 3A (AA′ direction view), FIG. 3C (CC′ direction view), and FIG. 5 (top view), FIG. 5A (AA′ direction view), and FIG. 5C (CC′ direction view), the structure comprises: a semiconductor substrate 200; a first doped region 202 that is formed within the semiconductor substrate and having a first type of doping; a gate 204 directly covering a portion of the substrate 200 where the first doped region is disposed, and a P-N junction formed within the semiconductor substrate 202; and a first contact 220 formed on the substrate 204 and second contacts 218 formed on the semiconductor substrate at both sides of the gate 204. The first contact 220 and the second contacts 218 are defined as cathode/anode of the diode device, respectively. The gate 204 may be formed by a semiconductor or compound semiconductor material that comprises one of Ge, SiGe, GaAs, InP, SiC, Si, and diamond, or combinations thereof.

In one embodiment, the gate 204 has a first type of doping, and the P-N junction is formed by the first doped region 202 and the second doped region 214 that is located in the semiconductor substrate at both sides of the gate 204 and has a second type of doping.

In another embodiment, the gate 204 has a second type of doping, and the P-N junction is formed by the gate and the first doped region 200/202 within the substrate bordered with the gate. Preferably, the structure may comprise a second doped region having a first type of doping within the semiconductor substrate underneath the second contact, so as to reduce the contact resistance.

Preferably, it may further comprise a cap layer 206 and 208 on the gate 204.

Preferably, it may comprise a metal silicide layer 217 that is formed between the second doped region and the second contact and between the first contact and the gate.

The semiconductor junction diode device structure and the method for manufacturing the same have been described above. In the present invention, a gate is directly formed on the substrate, a second contact is formed on the substrate, and a first contact is formed on the doped region at both sides of the gate. The first and second contacts act as cathode/anode of the diode device. Such a structure can reduce the device area. In addition, in the gate replacement process of an MOSFET device, a gate as a dummy gate of the MOSFET device will be removed in order to form a replacement gate. Therefore, formation of the diode device according to the present invention may be effectively integrated in the gate replacement process for the MOSFET device, which can reduce the cost of the manufacturing process and improve the integration level of the process.

Although the exemplary embodiments and their advantages have been described in detail, it is apparent to those having ordinary skill in the art that various alterations, substitutions and modifications may be made to the embodiments without departing from the spirit of the present invention and the scope as defined by the appended claims. For other examples, it may be easily recognized by a person of ordinary skill in the art that the order of the process steps may be changed without departing from the scope of the present invention.

In addition, the scope to which the present invention is applied is not limited to the process, mechanism, manufacture, material composition, means, methods and steps described in the specific embodiments in the specification. A person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A method for forming a semiconductor junction diode device, comprising:
A. providing a semiconductor substrate;
B. forming a first doped region having a first type of doping within the semiconductor substrate;
C. forming a gate directly covering a portion of the substrate where the first doped region is disposed, and forming a P-N junction within the semiconductor substrate; and
D. forming a first contact on the gate, and forming a second contact on the semiconductor substrate at both sides of the gate, the first contact and the second contact being defined as cathode/anode of the diode device, respectively.

2. The method according to claim 1, wherein the gate is formed by a semiconductor material or a compound semiconductor material.

3. The method according to claim 2, wherein the semiconductor material or the compound semiconductor material comprises one of Ge, SiGe, GaAs, InP, SiC, Si, and diamond, or combinations thereof.

4. The method according to claim 1, wherein step C further comprises: forming a gate having a first type of doping on the portion of the semiconductor substrate where the first doped region is disposed, and forming a second doped region having a second type of doping in the semiconductor substrate at both sides of the gate, thereby forming a P-N junction between the first doped region and the second doped region within the substrate.

5. The method according to claim 4, wherein the second doped region is formed by a doping process by which source/drain regions and/or shallow junction regions of MOSFET devices are formed.

6. The method according to claim 1, wherein the step C further comprises: forming a gate that has a second type of doping on the portion of the semiconductor substrate where the first doped region is disposed, and forming a P-N junction between the gate and the first doped region underneath the gate.

7. The method according to claim 6, wherein the step C further comprises: forming a second doped region that has a first type of doping within the semiconductor substrate at both sides of the gate.

8. The method according to claim 7, wherein the second doped region is formed by a doping process by which source/drain regions and/or shallow junction regions of MOSFET devices are formed.

9. The method according to claim 1, wherein between step C and step D, the method further comprises: forming a metal silicide layer between the second contact and the substrate underneath the second contact and between the first contact and the gate.

10. The method according to claim 1, further comprising forming a gate cap on the gate.

11. A semiconductor junction diode device structure, comprising:
a semiconductor substrate;
a first doped region having a first type of doping within the semiconductor substrate;
a gate directly covering a portion of the substrate where the first doped region is disposed, and a P-N junction formed within the semiconductor substrate; and
a first contact formed on the gate, and a second contact formed on the semiconductor substrate at both sides of the gate, the first contact and the second contact being defined as cathode/anode of the diode device, respectively.

12. The device structure according to claim 11, wherein the gate is formed by a semiconductor material or a compound semiconductor material.

13. The device structure according to claim 12, wherein the semiconductor material or the compound semiconductor material comprises one of Ge, SiGe, GaAs, InP, SiC, Si, and diamond, or combinations thereof.

14. The device structure according to claim 11, wherein the gate has a first type of doping.

15. The device structure according to claim 14, wherein the device structure further comprises a second doped region having a second type of doping and disposed at both sides of the gate in the semiconductor substrate, the P-N junction being formed by the second doped region and the first doped region.

16. The device structure according to claim 11, wherein the gate has a second type of doping.

17. The device structure according to claim 16, further comprising a second doped region having a first type of doping and formed within the semiconductor substrate underneath the second contact.

18. The device structure according to claim 16, wherein the P-N junction is formed by the gate and a first doped region located within the substrate adjacent to the gate.
